(19) United States
(12) Patent Application Publication
(10) Pub. No.: US 2004/0087116 A1
(43) Pub. Date: May 6, 2004

(54) Semiconductor devices and methods of manufacture thereof

(76) Inventor: Junichiro Nakayama, Nara (JP)

Correspondence Address: NIXON & VANDERHYE, PC, 1100 N GLEBE ROAD, 8TH FLOOR, ARLINGTON, VA, 22201-4714, US

(21) Appl. No.: 10/283,359

(22) Filed: Oct. 30, 2002

(51) Int. Cl. C30B 1/00

(52) U.S. Cl. 438/487

(57) ABSTRACT

In a method for manufacturing a semiconductor device and devices formed thereby, a semiconductor material (26) (e.g., amorphous silicon or microcrystallized silicon film) is formed on a substrate (22). At least a region (R) of the semiconductor material is irradiated with a laser (38) for heating and melting the semiconductor material in the region. The manufacturing method is controlled to promote uniform cooling of the semiconductor material in the irradiated region. Uniform cooling of the silicon film after irradiation is promoted so that, after irradiation, a desirable polycrystalline microstructure (CM) is formed in the semiconductor material by lateral solidification from a boundary (B) of the region. Uniform and/or slow cooling reduces occurrence of growth-restricting microcrystals in the center of the melted region, so that advantageously lateral crystal growth is relatively unrestricted, resulting in longer lateral growth and preferably also wider crystal growth essentially uniformly. In some modes of the invention, the process is controlled (and thus the cooling controlled) by providing a high thermal conductivity material (24B) in proximity to the semiconductor material. In other modes or as an optional step in modes having the high thermal conductivity material, the process is controlled (and thus the cooling controlled) by heating the semiconductor material to a temperature in a range from 300 degrees Centigrade to a crystallization temperature of the semiconductor material, particularly when using extended pulse laser irradiation.

### BACKGROUND

1. Field of the Invention

The present invention pertains to semiconductor materials and laser crystallization processes for making semiconductor integrated devices.

2. Related Art and Other Considerations

Some techniques for manufacturing semiconductor devices employ single crystallized silicon. Other techniques use a thin silicon film which has been deposited on a glass substrate. Examples of the latter technique include thin film transistor (TFT) devices of the type which serve as image controllers of an active matrix liquid crystal display (LCD).

Regarding the latter technique, previously the type of silicon which was employed as the thin silicon film was amorphous silicon. But the amorphous silicon film was characterized, among other things, by low mobility. More recently, therefore, polycrystalline silicon (which has relatively high mobility) has been utilized rather than amorphous silicon. For TFT-based image controllers, for example, usage of the polycrystalline silicon has improved the switching characteristics of the TFTs and overall increased the switching speed of images displayed on the LCD.

Typically polycrystalline silicon is obtained from amorphous silicon or a microcrystallized silicon film. One of the manufacturing methods for obtaining polycrystalline silicon is known as the excimer laser crystallization method (ELC). In the excimer laser crystallization method (ELC), an excimer laser irradiates a sample of an amorphous silicon film (or a microcrystallized silicon film) which resides on a substrate. The laser beam of the excimer laser (formed as a narrow rectangular beam having approximate dimensions of 200-400 mm on its long side and 0.2 to 1.0 mm on its short side) irradiates the sample while the beam moves at a uniform velocity across the sample. Irradiation of the sample tends to cause a partial melting of the irradiated area. That is, the melting occurs in a melting zone which extends only partially with respect to the depth (e.g., thickness) of the silicon film, leaving an underlying non-melting zone of the silicon film. Thus, the irradiated area of the sample does not melt completely, with the result that a crystallization or nucleation occurs at an interface between the non-melting zone and the melting zone. Many seeds for crystallization are produced at the interface. Crystals then grow vertically toward the surface of the film, with orientations of the crystals being random.

In the excimer laser crystallization method (ELC) as described above, the grain size of the crystals tends to be small, e.g., on the order of about 100 nm to 200 nm. Moreover, a potential wall of isolated electrons is formed at the grain boundary, and this potential wall has a strong scattering effect against the carrier. What really would be desired for the sake of enhancing high mobility of electrons would be a small number of grain boundaries or small number of grain boundary defects, and/or crystals of large grain size. But unfortunately the vertical and essentially random crystal growth promoted by the excimer laser crystallization method (ELC) is generally not conducive to a small number of grain boundaries and/or crystals of large grain size. Rather, the random crystallization facilitated by the excimer laser crystallization method (ELC) causes poor uniformity in the device structures. For a TFT-based image controller, for example, the random crystallization hampers the switching characteristics, there possibly being both fast switching pixels and low switching pixels in the very same display.

In view of the limitations of the excimer laser crystallization method (ELC), another method known as the sequential lateral solidification (SLS) method has been proposed. An example of the sequential lateral solidification (SLS) method is disclosed in U.S. Pat. No. 6,322,625, which is incorporated by reference herein in its entirety.

The sequential lateral solidification (SLS) method typically employs a pulsed laser which, through a mask slit, irradiates the sample (e.g., amorphous silicon semiconductor film) as the sample and laser are repetitively maneuvered so that adjacent or partially overlapping regions of the sample are irradiated in stepped fashion. In the sequential lateral solidification (SLS) method, the irradiation melts an exposed region of the sample essentially completely through its thickness, and (upon cooling) crystals grow toward the center of the irradiated region from its boundaries (i.e., interfaces of the irradiated region with two non-irradiated regions which neighbor the irradiated region). The reiterated stepped procedure results in polycrystals of needle-like shape having relatively long length.

In terms of crystal size, a single (one time) laser irradiation results in a needle-like crystal having a maximum length of about 1 micrometer. But a crystal of approximately 1 micrometer length is not sufficiently large to provide excellent device performance. Repeated irradiation as afforded by the sequential lateral solidification (SLS) method does increase the length of the needle-like crystal, but the width dimension of the crystal is not significantly enhanced. One of the things that is needed, therefore, is a polycrystalline silicon manufacturing technique which increases the grain size of a polycrystalline silicon crystal not only in length, but also in width, and uniformly so.

Other disclosed efforts fail to address and/or satisfy this or other needs. For example, Japanese Patent Application Publication H10-163112 endeavors to provide uniform crystals in an excimer laser crystallization method (ELC) technique involving a layer comprised of several different thermal conductivity materials which resides below the silicon film being crystallized. But a very complicated deposition technique is required to manufacture the multi-material layer.

Japanese Patent Application Publication 2000-244036 irradiates amorphous silicon with a pulse duration extended laser or continuous laser.

Japanese Patent Application Publication H6-345415 heats a semiconductor material and then re-crystallizes the amorphous silicon using another source.

Other disclosed efforts pertain to complete or partial melting, but in terms of crystal growth direction have control essentially only in a perpendicular direction (toward a surface of the film). For example, for the purpose of reducing defects, Japanese Patent Application Publication S61-187223 irradiates a semiconductor film with a pulse laser while applying a magnetic field orthogonally to the film. Japanese Patent Application Publication S63-96908 teaches irradiation of a semiconductor film with a pulse laser and application of a magnetic field perpendicular to the film for the purpose of smoothing the surface. Japanese Patent Application Publication 2000-182956 teaches irradiating a semiconductor film with a pulse laser longer than 100 ns and applying a magnetic field or electric field perpendicular or parallel to the film for enhancing orientation uniformity.

The need remains, therefore, and is an object of the present invention, for a polycrystalline silicon manufacturing technique which increases the grain size of a polycrystalline silicon crystal. An advantage of at least some aspects of the invention is a polycrystalline silicon manufacturing technique which increases the grain size of a polycrystalline silicon crystal, not only in length, but also in width, and uniformly so.

### BRIEF SUMMARY

In a method for manufacturing a semiconductor device and devices formed thereby, a semiconductor material (e.g., amorphous silicon or microcrystallized silicon film) is formed on a substrate. At least a region of the semiconductor material is irradiated with a laser for heating and melting the semiconductor material in the region. The manufacturing method is controlled to promote uniform cooling of the semiconductor material in the irradiated region. Uniform cooling of the silicon film after irradiation is promoted so that, after irradiation, a desirable polycrystalline microstructure is formed in the semiconductor material by lateral solidification from a boundary of the region. Uniform and/or slow cooling (rather than having rapid cooling in a specific sub-region as compared to other parts of the irradiated region) reduces occurrence of growth-restricting microcrystals in the center of the melted region, so that advantageously crystal growth is relatively unrestricted, resulting in longer lateral growth and preferably also wider crystal growth essentially uniformly.

In some modes of the invention, the process is controlled (and thus the cooling controlled) by providing a high thermal conductivity material in proximity to the semiconductor material. At least a region of the semiconductor material is irradiated with a laser for heating and melting the semiconductor material in the region. The high thermal conductivity material spreads heat in the region and promotes uniform cooling in the region, whereby after irradiation a polycrystalline microstructure is formed in the semiconductor material by lateral solidification from a boundary of the region.

The method can be performed using a sequential lateral solidification (SLS) process in which a beam from the laser is directed through a mask slit and onto the semiconductor material. That is, the irradiation can be performed sequentially with respect to adjacent or at least partially overlapping regions of the semiconductor device. The laser can be an extended laser or a continuous wave laser.

As used herein, “high thermal conductivity material” has a thermal conductivity of 10 W/mK or higher. In example, representative embodiments, the high thermal conductivity material is one of aluminum nitride; silicon nitride; a mixture of aluminum nitride and silicon nitride; magnesium oxide; cerium oxide; and titanium nitride.

In one non-limiting example embodiment, the high thermal conductivity material can be formed, for example, between the semiconductor material and the substrate. Additionally and optionally, a low thermal conductivity material can be formed between the high thermal conductivity material and the semiconductor material. Provision of the low thermal conductivity material can render the thickness of the high thermal conductivity material layer less significant, and further a low thermal conductivity material layer formed of a material such as silicon dioxide serves as a buffer to prevent contamination or reaction from the high thermal conductivity material to the silicon.

In other modes or as an optional step in modes having the high thermal conductivity material, the process is controlled (and thus the cooling controlled) by heating the semiconductor material to a temperature in a range from 300 degrees Centigrade to a crystallization temperature of the semiconductor material, particularly when using extended pulse laser irradiation. Extending the laser pulse duration and heating the semiconductor device to a temperature of 300 degrees Centigrade tends to make the temperature of the irradiated region of the semiconductor device uniform and the cooling velocity uniform. The process can be controlled so that the size (e.g., lengths) of the lateral growth crystals become even larger when the temperature is controlled to be (or be set) higher.

As another optional example step, a magnetic field is applied perpendicular to a surface of the semiconductor material during the laser irradiation. For example, in some modes a beam from the laser is directed through a mask slit and through the magnetic field onto the semiconductor material. In illustrative, non-limiting embodiments, the magnetic field may be generated by a magnet located in a sample stage upon which the semiconductor material is situated, or (alternatively) generated by a magnet whose core takes the form of a ring through which the laser beam is directed. In the process of silicon crystallization, sequential lateral growth crystals occur from the interface of the non-melting area and the melting area, meaning, e.g., that the silicon material moves in the melted area. Due to interaction between the magnetic field and this silicon material movement, a small electromotive force occurs. Then the interaction of the magnetic field and the electromotive force causes the length and width of the lateral growth crystals to become large and the orientation of the lateral growth crystals to become uniform.

Described herein also is a semiconductor device which has a semiconductor material formed on a substrate. The semiconductor material has a polycrystalline microstructure formed by lateral solidification after melting using laser irradiation. Some embodiments of the semiconductor device also has a high thermal conductivity material in proximity to the semiconductor material, the high thermal conductivity material having served for spreading heat in and promoting uniform cooling in the region after the irradiation. In one illustrated example embodiment, the high thermal conductivity material is between the semiconductor material and the substrate. Optionally and additionally, a low thermal conductivity material can be situated between the high thermal conductivity material and the semiconductor material.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1(A) is a schematic side view of a representative semiconductor device which can be fabricated in accordance with various example modes of manufacture.

FIG. 1(B) is a schematic side view of another representative semiconductor device which can be fabricated in accordance with various example modes of manufacture.

FIG. 2(A) is a schematic view of a first example embodiment of a laser irradiating manufacturing system suitable for performing manufacturing modes described herein to produce semiconductor devices of the types described herein.

FIG. 2(B) is a schematic view of a second example embodiment of a laser irradiating manufacturing system suitable for performing manufacturing modes described herein to produce semiconductor devices of the types described herein.

FIG. 2(C) is a schematic view of a third example embodiment of a laser irradiating manufacturing system suitable for performing manufacturing modes described herein to produce semiconductor devices of the types described herein.

FIG. 2(D) is a schematic view of a fourth example embodiment of a laser irradiating manufacturing system suitable for per forming manufacturing modes described herein to produce semiconductor devices of the types described herein.

FIG. 3, FIG. 3(B), and FIG. 3(C) are diagrammatic views of crystallized microstructures which exist in an irradiated region after a first time laser irradiation in accordance with various contrasting processes.

FIG. 4(A) and FIG. 4(B) are also diagrammatic views of crystallized microstructures which exist in an irradiated region after a first time laser irradiation in accordance with various other contrasting processes.

FIG. 5(A) and FIG. 5(B) are diagrammatic views of crystallized microstructures formed after repeated laser irradiation per a sequential lateral solidification (SLS) method in accordance with various contrasting processes.

FIG. 6(A), FIG. 6(B), FIG. 6(C), and FIG. 6(D) are diagrammatic views showing formation of crystallized microstructures during a sequence of steps of a sequential lateral solidification (SLS) method involving laser irradiation of a sequence of adjacent or at least partially overlapping regions.

### DETAILED DESCRIPTION OF THE DRAWINGS

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. For example, the semiconductor material herein described is not limited to silicon, nor are certain materials hereinafter described limited to those specifically mentioned. Nor is the invention limited by such factors as the example thickness of layers, alternative or optional steps, or type of laser, etc. In other instances, detailed descriptions of well-known devices, circuits, and methods are omitted so as not to obscure the description of the present invention with unnecessary detail.

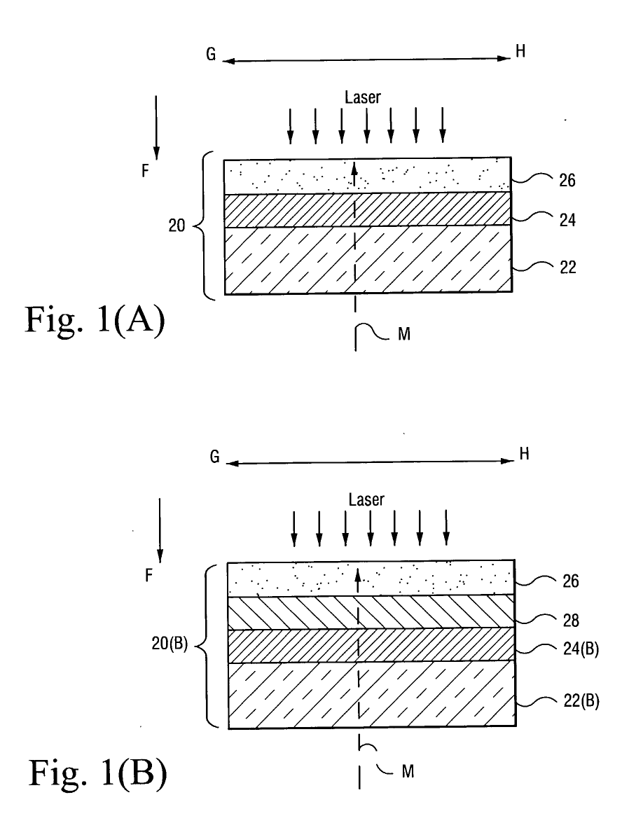

The semiconductor device 20 of FIG. 1(A) and the semiconductor device 20B of FIG. 1(B) serve in representative fashion to illustrate devices which can be fabricated in accordance with various example modes, including but not limited to the various specific modes of manufacturing methods described herein. For sake of convenience the semiconductor devices 20 and 20B will be referenced in conjunction with discussion of one or more modes hereinafter described, it being understood that the specific layers of the semiconductor devices 20 and 20B may differ from mode to mode.

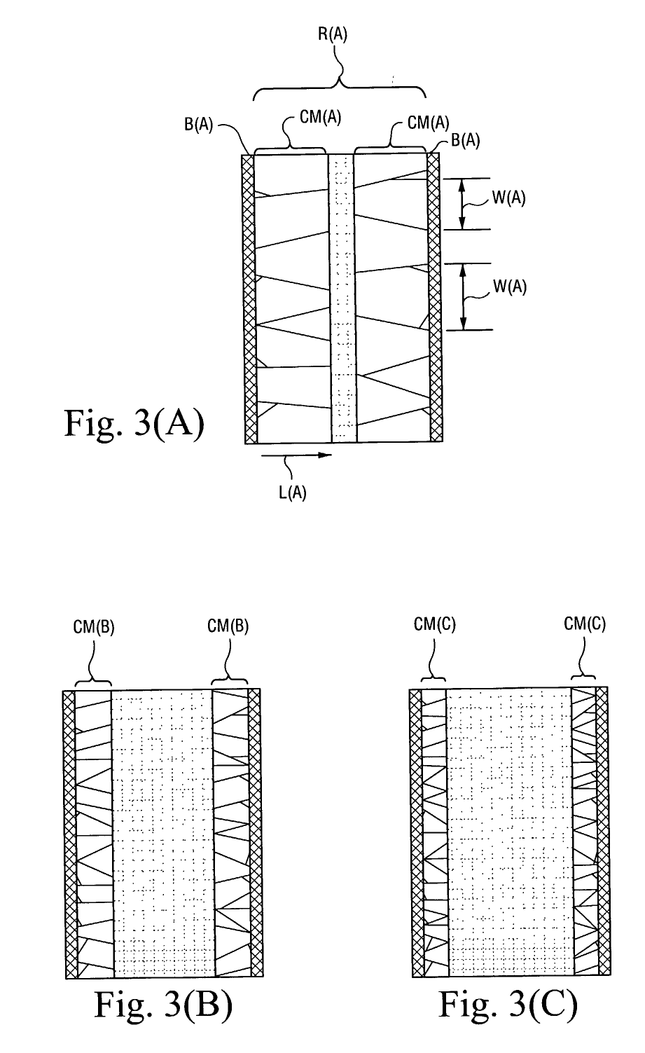

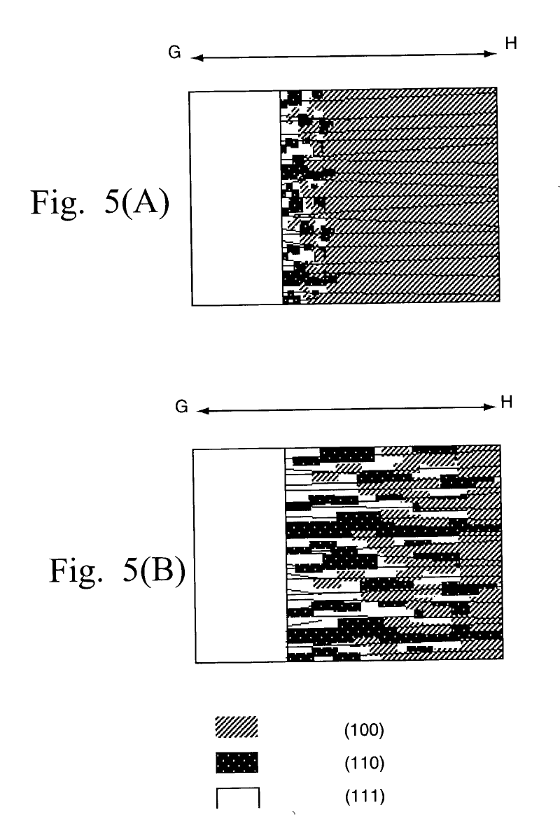

In similar manner, and again for sake of convenience, either FIG. 3(A), FIG. 3(B), and FIG. 3(C) on the one hand, or FIG. 5(A) and FIG. 5(B) on the other hand, are discussed in conjunction with various modes. Parameters or factors such as scale or length for these figures may differ in the various modes. In particular, FIG. 3(A), FIG. 3(B), and FIG. 3(C), and FIG. 5(A) and FIG. 5(B) are utilized herein as diagrammatic representations of crystallized microstructures which exist in an irradiated region after a first time laser irradiation (e.g., before any overlapping regions are sequentially exposed) in accordance with various processes. FIG. 3(A) is a diagrammatic representation of crystallized microstructure CM(A) which exists in an irradiated region R(A) after performance of the first nine modes; FIG. 5(A) is a diagrammatic representation of crystallized microstructure CM(A) which exists in an irradiated region R(A) after performance of the tenth through thirteenth modes disclosed herein. Typically FIG. 3(B) and FIG. 3(C) serve as diagrammatic representations of crystallized microstructure produced by processes (not necessarily prior art processes) which contrast with the first nine modes; while FIG. 5(B) serves as a diagrammatic representation of crystallized microstructure produced by processes (not necessarily prior art processes) which contrast with the tenth through thirteenth modes. Therefore, FIG. 3(A), FIG. 3(B), and FIG. 3(C), and FIG. 5(A) and FIG. 5(B), serve for sake of illustrating plural modes, although certain parameters associated with each mode may differ. More particularly, each of FIG. 3(A), FIG. 3(B), and FIG. 3(C), and FIG. 5(A) and FIG. 5(B), depicts the appearance of the silicon layer after performance of the respective process and after etching with a Secco etchant and examined using a scanning electron microscope (SEM).

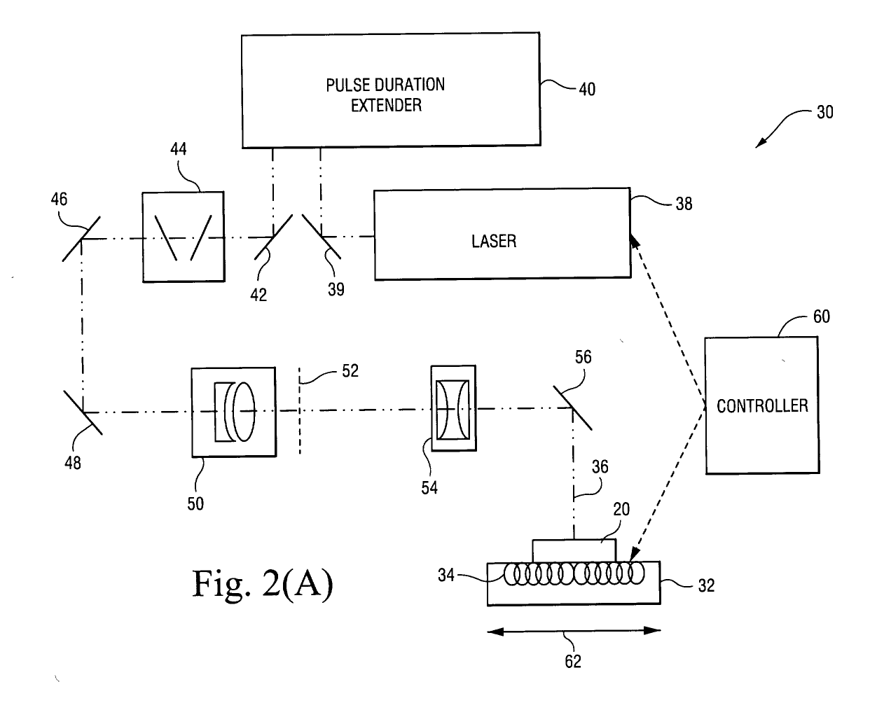

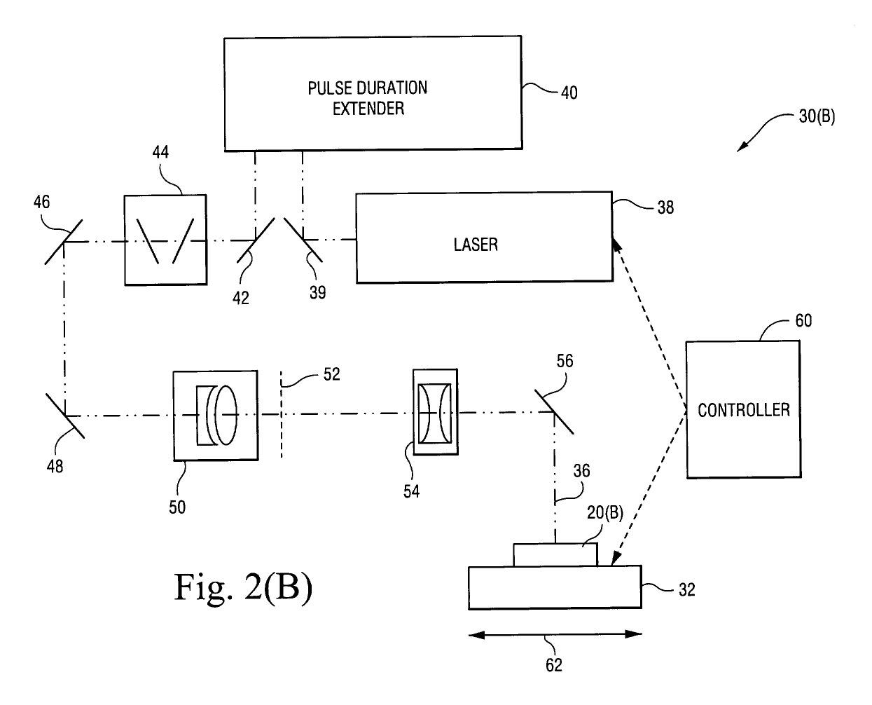

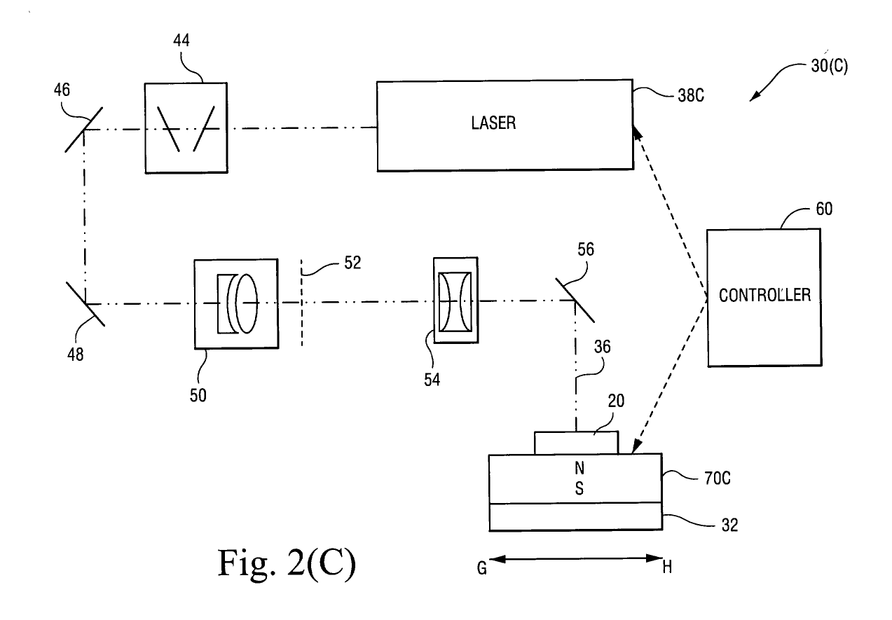

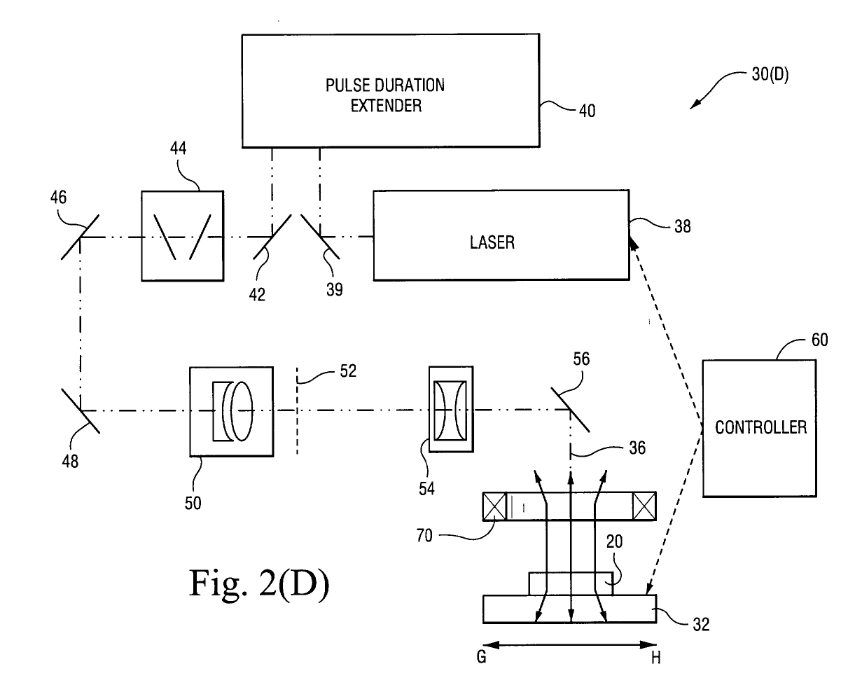

The various modes described herein can be implemented by suitable laser irradiating manufacturing systems, four example systems being illustrated in non-limiting fashion by FIG. 2(A), FIG. 2(B), FIG. 2(C), and FIG. 2(D), described hereinafter.

### First Mode

In accordance with a first mode, layer 24 of the semiconductor device 20 of FIG. 1(A) is a silicon dioxide layer which is formed on transparent substrate 22. The silicon dioxide layer 24 is deposited on transparent substrate 22 using any suitable technique, such as evaporation, ion-plating, sputtering, etc. An example thickness of the silicon dioxide layer 24 is 150 nm. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the first mode, steps performed after the depositions of the silicon dioxide layer 24 and silicon layer 26 on transparent substrate 22 as aforedescribed are performed in a system such as system 30 of FIG. 2(A). In system 30, the semiconductor device 20 is placed on sample stage 32 where it is heated by a heating device illustrated in FIG. 2(A) generically as heating device 34. The semiconductor material including silicon layer 26 is heated. While the semiconductor material including silicon layer 26 can be heated to any temperature in a range from 300 degrees Centigrade to a crystallization temperature of the silicon layer 26, in the particular example of the first mode the heating temperature is 300 degrees Centigrade.

A surface (e.g., top surface) of the silicon layer 26 is irradiated by a beam 36 emitted from pulsed laser 38. The beam 36 of the laser 38 is directed parallel to axis F shown in FIG. 1(A). In the example system, the pulse laser 38 is an excimer laser characterized by a wavelength of 308 nm (XeCl) and a pulse duration extended (using pulse duration extender 40). It will be appreciated that other types of lasers, such as a continuous wave solid laser, for example, could instead be used.

The energy of the irradiating beam 32 of the laser 38 transforms to heat energy and causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

FIG. 3(A) depicts the appearance of crystallized microstructure CM(A) in silicon layer 26 for the first mode. In actually, two areas of crystallized microstructure CM(A) of FIG. 3(A) extend from respective two opposing boundaries B(A) of the region R(A). The lengths of the crystals which result from the first mode are illustrated as arrow L(A) in FIG. 3(A); the widths of the crystals which result from the first mode are measured in a direction illustrated as arrow W(A) in FIG. 3(A).

By contrast, in terms of discussion of the first mode FIG. 3(B) and FIG. 3(C) depict crystallized microstructure CM(B) and CM(C), respectively, which result from prior art processes after one time laser irradiation. In the process which resulted in the crystallized microstructure CM(B) of FIG. 3(B), a pulse duration extended laser was utilized. In the process which resulted in the crystallized microstructure CM(C) of FIG. 3(C), a short pulse duration laser was used (not a pulse duration extended laser). In neither the process which resulted in the crystallized microstructure CM(B) of FIG. 3(B) nor the process which resulted in the crystallized microstructure CM(C) of FIG. 3(C) was there heating of the semiconductor device to a temperature in a range from 300 degrees Centigrade to a crystallization temperature of the silicon layer.

The lengths of the crystals which result from the first mode are illustrated as arrow L(A) in FIG. 3(A) and are on the order of 3.0 μm. The widths of the crystals which result from the first mode (measured in the direction illustrated as arrow W(A) in FIG. 3(A)) reach 1.0 μm. The effectiveness of the first mode is apparent from the fact that, e.g., the lengths of the crystals of FIG. 3(B) and FIG. 3(C) are shorter, i.e., 2.0 μm and 1.0 μm, respectively, and the widths of the crystals of FIG. 3(B) and FIG. 3(C) are narrower, i.e., on the order of about 0.5 μm.

The thermal conductivity of the silicon dioxide used as layer 24 in the first mode is similar to that of silicon, e.g., about 1 (W/mK). Therefore, in the process of silicon crystallization, silicon dioxide cannot widely spread the heat received from the irradiation, and similarly cannot make the cooling velocity of the silicon uniform. But as the first mode demonstrates, extending the laser pulse duration makes the temperature of the irradiated region of the semiconductor device 20 uniform and the cooling velocity uniform. The heating of the semiconductor material to a temperature of 300 degrees Centigrade or greater also slows the cooling. The fact that the cooling occurs uniformly (rather than having rapid cooling in a specific sub-region as compared to other parts of the irradiated region) and is slowed reduces the occurrence of microcrystals in the center of the melted region. The microcrystals were undesirable since they tended to restrict sequential lateral growth from the interface of a non-melting area and the melted region. But advantageously the first mode exhibits crystal growth which is relatively unrestricted, resulting in longer lateral growth and preferably also wider crystal growth essentially uniformly.

Both the lengths and widths of the lateral growth crystals can become even larger when the temperature is higher. For example, when the semiconductor device 20 is heated to 450 degrees Centigrade, the length of the lateral growth crystals reaches 4.5 μm and the width of the lateral growth crystals reaches 1.5 μm. At 600 degrees Centigrade the length of the lateral growth crystals reaches 7.0 μm and the width of the lateral growth crystals reaches 2.5 μm.

### Second Mode

In accordance with a second mode, layer 24 of the semiconductor device 20 of FIG. 1(A) is a high thermal conductivity layer which is formed on transparent substrate 22. As used herein, “high thermal conductivity material” has a thermal conductivity of 10 W/mK or higher. For the second mode, the high thermal conductivity layer 24 is made of aluminum nitride. The aluminum nitride high thermal conductivity layer 24 is deposited on transparent substrate 22 using any suitable technique, such as evaporation, ion-plating, sputtering, etc. An example thickness of the aluminum nitride high thermal conductivity layer 24 is 25 nm. Layer 26 of the semiconductor device 20 of FIG. 1(A) is silicon layer 26 which can be deposited on the high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the second mode, steps performed after the depositions of the aluminum nitride high thermal conductivity layer 24 and silicon layer 26 on transparent substrate 22 as aforedescribed are performed in a system such as system 30(B) of FIG. 2(B). In system 30(B), the semiconductor device 20 is placed on sample stage 32 at room temperature. A surface (e.g., top surface) of the silicon layer 26 is irradiated by a beam 36 emitted from pulsed laser 38. The beam 36 of the laser 38 is directed parallel to axis F shown in FIG. 1(A). In the example system, the pulse laser 38 is an excimer laser utilized with pulse duration extender 40. Again it will be appreciated that other types of lasers, such as a continuous wave solid laser, for example, could instead be used.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

FIG. 3(A) is a diagrammatic representation of crystallized microstructure CM(A) which exists in a region R(A) after a first time laser irradiation (e.g., before any overlapping regions are sequentially exposed) in accordance with the second mode. By contrast, FIG. 3(B) and FIG. 3(C) depict crystallized microstructure CM(B) and CM(C), respectively, which result from other processes after one time laser irradiation, the process for FIG. 3(C) being a prior art process for the second mode.

In the process which resulted in the crystallized microstructure CM(B) of FIG. 3(B), a short pulse duration laser was utilized (not a pulse duration extended laser) and a high thermal conductivity layer 24 was formed. In the process which resulted in the crystallized microstructure CM(C) of FIG. 3(C), on the other hand, a short pulse duration laser was used but no high thermal conductivity layer was formed.

The lengths of the crystals which result from the second mode are illustrated as arrow L(A) in FIG. 3(A) and are on the order of 3.5 μm. The widths of the crystals which result from the second mode (measured in the direction illustrated as arrow W(A) in FIG. 3(A)) reach 1.2 μm. The effectiveness of the second mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

The thermal conductivity of the aluminum nitride high thermal conductivity layer 24 in the second mode is about 35 (W/mK), which is considerably higher than the thermal conductivity of silicon (about 1 (W/mK)). Therefore, in the process of silicon crystallization of the second mode, the aluminum nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. As stated before, the microcrystals were undesirable since they tended to restrict sequential lateral growth from the interface of a non-melting area and the melted region. But advantageously the second mode exhibits crystal growth which is relatively unrestricted, resulting in longer lateral growth and preferably also wider crystal growth essentially uniformly.

The thickness of the layer of the high thermal conductivity material is determined in accordance with its thermal conductivity. The thickness of the layer will be thin when the thermal conductivity material is high; the thickness of the layer will be thick when the high thermal conductivity material is low. If the thermal conductivity is too high, the suitable range of thickness is small, for which reason a low thermal conductivity material may be used in the manner hereinafter described, e.g., to reduce sensitivity. Typically for the embodiments described herein the thickness of the high thermal conductivity material layer can be on the order of 20 to 30 nm.

### Third Mode

Like in the second mode, in the third mode layer 24 of the semiconductor device 20 of FIG. 1(A) is a high thermal conductivity layer which is formed on transparent substrate 22. But the constituency of the high thermal conductivity layer 24 for the third mode differs from the second mode. In the third mode, the high thermal conductivity layer 24 is made of silicon nitride. The silicon nitride high thermal conductivity layer 24 is deposited on transparent substrate 22 using any suitable technique, such as evaporation, ion-plating, sputtering, etc. An example thickness of the high thermal conductivity layer 24 is 50 nm. Layer 26 of the semiconductor device of FIG. 1(A) is silicon layer 26 which can be deposited on the silicon nitride high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the third mode, steps performed after the depositions of the silicon nitride high thermal conductivity layer 24 and silicon layer 26 on transparent substrate 22 as aforedescribed are performed at room temperature in a system such as system 30(B) of FIG. 2(B). The subsequent steps of the third mode are essentially the same as the second mode, it being understood, however, that the high thermal conductivity layer is made of silicon nitride rather than aluminum nitride.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary. In the process of silicon crystallization of the third mode, the silicon nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the third mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the third mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed. In the process which resulted in the crystallized microstructure CM(C) of FIG. 3(C), on the other hand, a short pulse duration laser was used and no high thermal conductivity layer was formed.

The lengths of the crystals which result from the third mode are illustrated as arrow L(A) in FIG. 3(A) and are on the order of 3.5 μm. The widths of the crystals which result from the third mode (measured in the direction illustrated as arrow W(A) in FIG. 3(A)) reach 1.2 μm. The effectiveness of the third mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

The thermal conductivity of the silicon nitride high thermal conductivity layer 24 in the third mode is lower than the aluminum nitride used for the high thermal conductivity layer in the second mode. In particular, the thermal conductivity of the silicon nitride high thermal conductivity layer is about 10 (W/mK). However, the silicon nitride matches with the silicon layer 26 well because of the common element of silicon in both layers. Moreover, both the silicon nitride for the high thermal conductivity layer and the silicon layer can be deposited with CVD or sputtering using the same target of silicon continuously, thereby rendering the manufacturing process quite efficient and economical.

### Fourth Mode

Like in the second mode and third mode, in the fourth mode layer 24 of the semiconductor device 20 of FIG. 1(A) is a high thermal conductivity layer which is formed on transparent substrate 22. But the constituency of the high thermal conductivity layer 24 for the fourth mode differs from the previous modes. In the fourth mode, the high thermal conductivity layer 24 is a mixture of aluminum nitride and silicon nitride. The aluminum nitride and silicon nitride high thermal conductivity layer 24 is deposited on transparent substrate 22 using any suitable technique, such as evaporation, ion-plating, sputtering, etc. An example thickness of the aluminum nitride and silicon nitride high thermal conductivity layer 24 is 40 nm. Layer 26 of the semiconductor device 20 of FIG. 1(A) is silicon layer 26 which can be deposited on the high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the fourth mode, steps performed after the depositions of the high thermal conductivity layer 24 and silicon layer 26 on transparent substrate 22 as aforedescribed are performed at room temperature in a system such as system 30(B) of FIG. 2(B). The subsequent steps of the fourth mode are essentially the same as the second and third modes, it being understood, however, that the high thermal conductivity layer is a mixture of aluminum nitride and silicon nitride, rather than just one of silicon nitride (third mode) or aluminum nitride (second mode).

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer 24 made of the mixture of aluminum nitride and silicon nitride is about 20 (W/mK). Therefore, in the process of silicon crystallization of the fourth mode, the aluminum nitride and silicon nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the fourth mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the fourth mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed. In the process which resulted in the crystallized microstructure CM(C) of FIG. 3(C), on the other hand, a short pulse duration laser was used and no high thermal conductivity layer was formed.

The lengths of the crystals which result from the fourth mode are illustrated as arrow L(A) in FIG. 3(A) and are on the order of 3.5 μm. The widths of the crystals which result from the fourth mode (measured in the direction illustrated as arrow W(A) in FIG. 3(A)) reach 1.2 μm. The effectiveness of the fourth mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

The thermal conductivity of the layer 24 can be changed according to the composition ratio of aluminum nitride and silicon nitride, so that layers of suitable thickness and design can be easily implemented suitable to a particular laser system.

### Fifth Mode

Like in all previous modes except the first mode, in the fifth mode layer 24 of the semiconductor device 20 of FIG. 1(A) is a high thermal conductivity layer which is formed on transparent substrate 22. But the constituency of the high thermal conductivity layer 24 for the fifth mode differs from the previous modes. In the fifth mode, the high thermal conductivity layer 24 is magnesium oxide. The magnesium oxide high thermal conductivity layer 24 is deposited on transparent substrate 22 using any suitable technique, such as evaporation, ion-plating, sputtering, etc. An example thickness of the magnesium oxide high thermal conductivity layer 24 is 20 nm. Layer 26 of the semiconductor device 20 of FIG. 1(A) is silicon layer 26 which can be deposited on the magnesium oxide high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the fifth mode, steps performed after the depositions of the magnesium oxide high thermal conductivity layer 24 and silicon layer 26 on transparent substrate 22 as aforedescribed are performed at room temperature in a system such as system 30(B) of FIG. 2(B). The subsequent steps of the fifth mode are essentially the same as the previously described modes (excepting the first mode), it being understood, however, that the high thermal conductivity layer is made of magnesium oxide.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer made of magnesium oxide is about 60 (W/mK). Therefore, in the process of silicon crystallization of the fifth mode, the magnesium oxide high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the fifth mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the fifth mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed. In the process which resulted in the crystallized microstructure CM(C) of FIG. 3(C), on the other hand, a short pulse duration laser was used and no high thermal conductivity layer was formed.

The lengths of the crystals which result from the fifth mode are illustrated as arrow L(A) in FIG. 3(A) and are on the order of 3.5 μm. The widths of the crystals which result from the fifth mode (measured in the direction illustrated as arrow W(A) in FIG. 3(A)) reach 1.2 μm. The effectiveness of the fifth mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

In addition to its high thermal conductivity, magnesium oxide also advantageously has uniform orientation of crystals. For instance, magnesium oxide can be arranged with an orientation of (111) in order to increase the possibility of obtaining uniform orientation of silicon layer 26, with such uniformity enhancing mobility of the semiconductor device 20.

### Sixth Mode

Like in all previous modes except the first mode, in the sixth mode layer 24 of the semiconductor device 20 of FIG. 1(A) is a high thermal conductivity layer which is formed on transparent substrate 22. But the constituency of the high thermal conductivity layer 24 for the sixth mode differs from the previous modes. In the sixth mode, the high thermal conductivity layer 24 is cerium oxide. The cerium oxide high thermal conductivity layer 24 is deposited on transparent substrate 22 using any suitable technique, such as evaporation, ion-plating, sputtering, etc. An example thickness of the cerium oxide high thermal conductivity layer 24 is 50 nm. Layer 26 of the semiconductor device 20 of FIG. 1(A) is silicon layer 26 which can be deposited on the cerium oxide high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the sixth mode, steps performed after the depositions of the cerium oxide high thermal conductivity layer 24 and silicon layer 26 on transparent substrate 22 as aforedescribed are performed at room temperature in a system such as system 30(B) of FIG. 2(B). The subsequent steps of the sixth mode are essentially the same as the previously described modes (excepting the first mode), it being understood, however, that the high thermal conductivity layer is made of cerium oxide.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer made of cerium oxide is about 10 (W/mK). Therefore, in the process of silicon crystallization of the sixth mode, the cerium oxide high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the sixth mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the sixth mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed. In the process which resulted in the crystallized microstructure CM(C) of FIG. 3(C), on the other hand, a short pulse duration laser was used and no high thermal conductivity layer 24 was formed.

The lengths of the crystals which result from the sixth mode are illustrated as arrow L(A) in FIG. 3(A) and are on the order of 3.5 μm. The widths of the crystals which result from the sixth mode (measured in the direction illustrated as arrow W(A) in FIG. 3(A)) reach 1.2 μm. The effectiveness of the sixth mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

Like the magnesium oxide of the fifth example, the cerium oxide also advantageously has uniform orientation of crystals, thereby enhancing mobility of the semiconductor device 20. Moreover, the lattice constant of cerium is 5.41 Angstroms, similar to that of silicon (5.43 Angstroms), so that a high thermal conductivity layer 24 of cerium oxide well matches with silicon layer 26.

### Seventh Mode

Like in all previous modes except the first mode, in the seventh mode layer 24 of the semiconductor device 20 of FIG. 1(A) is a high thermal conductivity layer which is formed on transparent substrate 22. But the constituency of the high thermal conductivity layer 24 for the seventh mode differs from the previous modes. In the seventh mode, the high thermal conductivity layer 24 is titanium nitride. The titanium nitride high thermal conductivity layer 24 is deposited on transparent substrate 22 using any suitable technique, such as evaporation, ion-plating, sputtering, etc. An example thickness of the titanium nitride high thermal conductivity layer 24 is 40 nm. Layer 26 of the semiconductor device 20 of FIG. 1(A) is silicon layer 26 which can be deposited on the titanium nitride high thermal conductivity layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the seventh mode, steps performed after the depositions of the titanium nitride high thermal conductivity layer 24 and silicon layer 26 on transparent substrate 22 as aforedescribed are performed at room temperature in a system such as system 30(B) of FIG. 2(B). The subsequent steps of the seventh mode are essentially the same as the previously described modes (excepting the first mode), it being understood, however, that the high thermal conductivity layer is made of titanium nitride.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer made of titanium nitride is about 15 (W/mK) at room temperature and about 50 (W/mK) at temperatures above 1000 degrees Centigrade. Therefore, in the process of silicon crystallization of the seventh mode, the titanium nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the seventh mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the seventh mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed. In the process which resulted in the crystallized microstructure CM(C) of FIG. 3(C), on the other hand, a short pulse duration laser was used and no high thermal conductivity layer 24 was formed.

The lengths of the crystals which result from the seventh mode are illustrated as arrow L(A) in FIG. 3(A) and are on the order of 3.5 μm. The widths of the crystals which result from the seventh mode (measured in the direction illustrated as arrow W(A) in FIG. 3(A)) reach 1.2 μm. The effectiveness of the seventh mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

### Eighth Mode

In accordance with an eighth mode, layer 24B of the semiconductor device 20B of FIG. 1(B) is a high thermal conductivity layer which is formed on transparent substrate 22. Layer 28 of semiconductor device 20B is a low thermal conductivity layer. Both the high thermal conductivity layer 24B and the low thermal conductivity layer 28 can be deposited (separately) using any suitable technique, such as evaporation, ion-plating, sputtering, etc. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

This eighth mode features, e.g., the use of low thermal conductivity layer 28. In the representative example implementation of the eighth mode now discussed, an example material for the low thermal conductivity layer 28 is silicon oxide formed in a layer having a thickness of about 10 nm. Also in the particular example implementation now discussed, a representative example for the high thermal conductivity layer 24 is a layer made of aluminum nitride. An example thickness of the aluminum nitride high thermal conductivity layer 24 is 25 nm. It should be understood that the composition of the high thermal conductivity layer 24 is not limited to aluminum nitride. Rather, any high thermal conductivity material such as those discussed with reference to the preceding second through seventh modes can instead be utilized for high thermal conductivity layer 24. Table 1 provides thermal conductivity values for certain materials.

TABLE 1
CONDUCTIVITY OF MATERIALS

| MATERIAL | THERMAL CONDUCTIVITY (W/mK) |
|---|---|
| AlN | ˜35 |
| SiNx | ˜10 |
| AlSiN | ˜20 |
| MgO | ˜60 |
| CeO₂ | ˜10 |
| TiN | ˜15 (room temp); ˜50 (>1000C) |
| Glass | ˜0.8 |
| SiO₂ | ˜1.4 |
| a-Si | ˜1.0 |

Thus, like in all previous modes except the first mode, in the eighth mode layer 24B of the semiconductor device 20B of FIG. 1(B) is a high thermal conductivity layer which is formed on transparent substrate 22. For the eighth mode, steps performed after the depositions of the aluminum nitride high thermal conductivity layer 24, the low thermal conductivity layer 28, and the silicon layer 26 on transparent substrate 22 as aforedescribed are performed at room temperature in a system such as system 30(B) of FIG. 2(B). The subsequent steps of the eighth mode are essentially the same as the previously described modes (excepting the first mode), it being understood, however, that the high thermal conductivity layer is made of aluminum nitride and that the low thermal conductivity layer 28 have been formed between the high thermal conductivity layer and silicon layer 26.

The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer made of aluminum nitride is about 35 (W/mK). Therefore, in the process of silicon crystallization of the eighth mode, the aluminum nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the eighth mode exhibits crystal growth which is relatively unrestricted, resulting in longer lateral growth and preferably also wider crystal growth essentially uniformly.

Provision of the low thermal conductivity material layer 28 can render the thickness of the high thermal conductivity material layer 24B less significant. Further a low thermal conductivity material layer 28 formed of a material such as silicon dioxide serves as a buffer to prevent contamination or reaction from the high thermal conductivity material to the silicon. These considerations apply to other modes hereof which employ a low thermal conductivity material layer.

FIG. 3(A) is a diagrammatic representation of crystallized microstructure CM(A) which exists in a region R(A) after a first time laser irradiation (e.g., before any overlapping regions are sequentially exposed) in accordance with the eighth mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed with a low thermal conductivity layer. In the process which resulted in the crystallized microstructure CM(C) of FIG. 3(C), on the other hand, a short pulse duration laser was used and no high thermal conductivity layer 24 was formed.

The lengths of the crystals which result from the eighth mode are illustrated as arrow L(A) in FIG. 3(A) and are on the order of 3.5 μm. The widths of the crystals which result from the eighth mode (measured in the direction illustrated as arrow W(A) in FIG. 3(A)) reach 1.2 μm. The effectiveness of the eighth mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

### Ninth Mode

In accordance with a ninth mode, layer 24B of the semiconductor device 20B of FIG. 1(B) is a high thermal conductivity layer and layer 28 is a low thermal conductivity layer. Both the high thermal conductivity layer 24B and the low thermal conductivity layer 28 can be deposited (separately) using any suitable technique, such as evaporation, ion-plating, sputtering, etc. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

As in the eighth mode, for the ninth mode the example, representative materials for the low thermal conductivity layer 28 and the high thermal conductivity layer 24 are silicon oxide (about 10 nm) and aluminum nitride(25 nm), respectively. Again, it should be understood that the composition of the high thermal conductivity layer 24 is not limited to aluminum nitride nor is the composition of low thermal conductivity layer 28 limited to silicon oxide, but that other suitable materials as previously discussed can instead be utilized.

As in the first mode, steps performed in the ninth mode after the depositions of the high thermal conductivity layer, the low thermal conductivity layer 28, and the silicon layer 26 as aforedescribed are performed in a system such as system 30 of FIG. 2(A). In system 30, the semiconductor device 20B is placed on sample stage 32 where it is heated by a heating device illustrated in FIG. 2(B) generically as heating device 34. The semiconductor material including silicon layer 26 is heated. While the semiconductor material including silicon layer 26 can be heated to any temperature in a range from 300 degrees Centigrade to a crystallization temperature of the silicon layer 26, in the particular example of the ninth mode the heating temperature is 300 degrees Centigrade.

A surface (e.g., top surface) of the silicon layer 26 is irradiated by a beam 36 emitted from pulsed laser 38. The beam 36 of the laser 38 is directed parallel to axis F shown in FIG. 1(B). The beam 32 of the laser 38 causes a first melting in a region of the amorphous silicon layer 26 which was in the field of the beam 32. The melting occurs essentially through the entire thickness of the layer 26 in the irradiated region. As the melted silicon cools, the silicon crystallizes. In particular, a polycrystalline microstructure is formed in the irradiated region of the silicon layer 26 by lateral solidification from a boundary.

The thermal conductivity of the high thermal conductivity layer made of aluminum nitride is about 35 (W/mK). Therefore, in the process of silicon crystallization of the ninth mode, the aluminum nitride high thermal conductivity layer 24 widely spreads the heat received from the irradiation and makes the cooling velocity of the silicon uniform. Extending the laser pulse duration also serves to widely spread the heat received from the irradiation and make the cooling velocity of the silicon uniform. The fact that the cooling occurs uniformly (rather than having rapid cooling in a specific sub-region as compared to other parts of the irradiated region) reduces occurrence of microcrystals in the center of the melted region. Advantageously the ninth mode exhibits crystal growth which is relatively unrestricted, resulting in longer lateral growth and preferably also wider crystal growth essentially uniformly.

FIG. 3(A) is a diagrammatic representation of crystallized microstructure CM(A) which exists in a region R(A) after a first time laser irradiation (e.g., before any overlapping regions are sequentially exposed) in accordance with the ninth mode. By contrast, FIG. 3(B) and FIG. 3(C) depict crystallized microstructure CM(B) and CM(C), respectively, which result from other processes after one time laser irradiation, the process for FIG. 3(C) being a prior art process. In the process which resulted in the crystallized microstructure CM(B) of FIG. 3(B), a short pulse duration laser was utilized (not a pulse duration extended laser) and the high thermal conductivity layer 24 was formed with a low thermal conductivity layer. In the process which resulted in the crystallized microstructure CM(C) of FIG. 3(C), on the other hand, a short pulse duration laser was used and no high thermal conductivity layer 24 was formed.

The lengths of the crystals which result from the ninth mode are illustrated as arrow L(A) in FIG. 3(A) and are on the order of 3.5 μm. The widths of the crystals which result from the ninth mode (measured in the direction illustrated as arrow W(A) in FIG. 3(A)) reach 1.2 μm. The effectiveness of the ninth mode is apparent from the fact that, e.g., the lengths of the crystals of FIG. 3(B) and FIG. 3(C) are shorter, i.e., 2.5 μm and 1.0 μm, respectively, and the widths of the crystals of FIG. 3(B) and FIG. 3(C) are narrower, i.e., on the order of about 0.8 μm.

In accordance with the ninth mode, the lengths of the lateral growth crystals can become even larger when the temperature is higher. For example, when the semiconductor device 20 is heated to 450 degrees Centigrade, the length of the lateral growth crystals reaches 4.5 μm and the width of the lateral growth crystals reaches 1.5 μm. At 600 degrees Centigrade the length of the lateral growth crystals reaches 7.0 μm. and the width of the lateral growth crystals reaches 2.5 μm.

For the modes in which both the high thermal conductivity layer and the low thermal conductivity layer are employed, the composite thermal conductivity effect of the high thermal conductivity layer and the low thermal conductivity layer and thus the degree of heat/cooling spreading can be changed, adjusted, or controlled in accordance with a thickness ratio of the low thermal conductivity layer to the high thermal conductivity layer. This thermal conductivity control capability facilitates compatibility for differing laser systems and utilization for differing types of semiconductor devices.

### Tenth Mode

In accordance with a tenth mode, layer 24 of the semiconductor device 20 of FIG. 1(A) is a silicon dioxide layer which is formed on transparent substrate 22. The silicon dioxide layer 24 is deposited on transparent substrate 22 using any suitable technique, such as evaporation, ion-plating, sputtering, etc. An example thickness of the silicon dioxide layer 24 is 150 nm. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the tenth mode, steps performed after the depositions of the silicon dioxide layer 24 and silicon layer 26 on transparent substrate 22 as aforedescribed are performed in a system such as system 30C of FIG. 2(C). In system 30C, the semiconductor device 20 is placed on sample stage 32. At room temperature, a surface (e.g., top surface) of the silicon layer 26 is irradiated by a beam 36 emitted from pulsed laser 38C (a short pulse duration laser) and a magnetic field is applied by magnet 70C (see FIG. 2(C)). The beam 36 of the laser 38C is directed parallel to axis F shown in FIG. 1(A), and the lines of force of the magnetic field are also parallel to the axis F. In other words, the magnetic field is perpendicular to a top surface of silicon layer 26. Application of the magnetic field is depicted by broken arrow M in FIG. 1(A) (arrow M being broken to reflect the fact that the magnetic field is not applied in all modes served for illustration purposes by FIG. 1(A)). The magnetic field is applied at approximately 300 kA/m.

The energy of the irradiating beam 32 of the laser 38C transforms to heat energy and causes a first melting in a region of the amorphous silicon layer 26 which was in the field of the beam 32. The melting occurs essentially through the entire thickness of the layer 26 in the irradiated region. The silicon layer 26 has low electric conductivity at room temperature, but high electric conductivity when it melts. As the melted silicon cools, the silicon crystallizes. In particular, a polycrystalline microstructure is formed in the irradiated region of the silicon layer 26 by lateral solidification from a boundary. In the process of silicon crystallization, sequential lateral growth crystals occur from the interface of the non-melting area and the melting area, meaning, e.g., that the silicon material moves in the melted area. Due to interaction between the magnetic field (generated by magnet 70C) and this silicon material movement, a small electromotive force occurs. Then the interaction of the magnetic field and the electromotive force causes the length and width of the lateral growth crystals to become large and the orientation of the lateral growth crystals to become uniform.

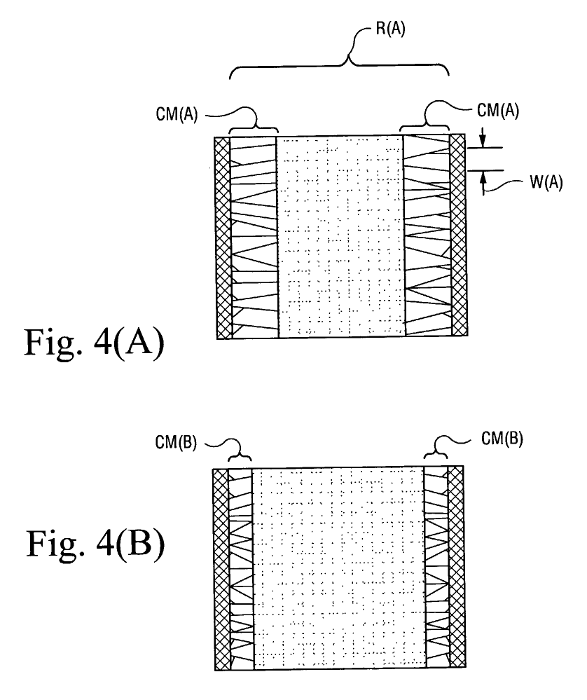

FIG. 4(A) is a diagrammatic representation of crystallized microstructure CM(A) which exists in a region R(A) after a first time laser irradiation (e.g., before any overlapping regions are sequentially exposed) in accordance with the tenth mode. By contrast, FIG. 4(B) depicts crystallized microstructure CM(B) which results from other processes after one time laser irradiation. In particular, in the process which resulted in the crystallized microstructure CM(B) of FIG. 4(B), a short pulse duration laser was utilized but no magnetic field was applied.

Whereas FIG. 4(A) shows crystallized microstructure after a first time or one-shot process in accordance with the tenth mode, FIG. 5(A) is a diagrammatic representation of crystallized microstructure CM(A) after repeated stepped laser irradiation using a sequential lateral solidification (SLS) method in accordance with the tenth mode. Whereas the one shot process which yields the structure of FIG. 4(A) a resultant device such as a TFT must be made in the crystal grain, in the SLS method of FIG. 5(A) the TFT device can be made anywhere along the SLS direction.

By contrast to FIG. 5(A), FIG. 5(B) depicts crystallized microstructure CM(A) which exists after repeated stepped laser irradiation using a sequential lateral solidification (SLS) method in accordance with the process utilized to produce FIG. 4(B), i.e., using a short pulse duration laser but no magnetic field.

The lengths of the crystals which result from the tenth mode are illustrated as arrow L(A) in FIG. 4(A) and are on the order of 2.5 μm. The widths of the crystals which result from the tenth mode (measured in the direction illustrated as arrow W(A) in FIG. 4(A)), reach 0.8 μm. The effectiveness of the tenth mode is apparent from the fact that, e.g., the length of the crystals of FIG. 4(B) are shorter, i.e., about 1.0 μm, and the widths of the crystals of FIG. 4(B) are narrower, i.e., on the order of about 0.5 μm.

In FIG. 5(A) and FIG. 5(B), the white area is (111) orientation, the light gray area is (101) orientation, and the deep gray area is (100) orientation along the G-H axis. The contrast of FIG. 5(A) and FIG. 5(B) indicate that the tenth mode has more uniformity in crystal orientation than the prior art.

### Eleventh Mode

In accordance with an eleventh mode, and somewhat similar to the eighth mode, layer 24B of the semiconductor device 20B of FIG. 1(B) is a high thermal conductivity layer which is formed on transparent substrate 22. Layer 28 of semiconductor device 20B is a low thermal conductivity layer. Both the thermal conductivity layer 24B and the low thermal conductivity layer 28 can be deposited (separately) using any suitable technique, such as evaporation, ion-plating, sputtering, etc. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

In the representative example implementation of the eleventh mode now discussed, an example material for the low thermal conductivity layer 28 is silicon oxide formed in a layer having a thickness of about 10 nm. Also in the particular example implementation now discussed, a representative example for the high thermal conductivity layer 24 is a layer made of aluminum nitride. An example thickness of the aluminum nitride high thermal conductivity layer 24 is 25 nm. It should be understood that the composition of the high thermal conductivity layer 24 is not limited to aluminum nitride. Rather, any high thermal conductivity material such as those discussed with reference to the preceding second through seventh modes can instead be utilized for high thermal conductivity layer 24.

For the eleventh mode, steps performed after the depositions of the aluminum nitride high thermal conductivity layer 24, the low thermal conductivity layer 28, and the silicon layer 26 on transparent substrate 22 as aforedescribed are performed at room temperature in a system such as system 30(C) of FIG. 2(C). At room temperature, a surface (e.g., top surface) of the silicon layer 26 is irradiated by a beam 36 emitted from pulsed laser 38C (a short pulse duration laser) and a magnetic field is applied by magnet 70C (see FIG. 2(C)). The beam 36 of the laser 38C is directed parallel to axis F shown in FIG. 1(A), and the lines of force of the magnetic field are also parallel to the axis F. In other words, the magnetic field is perpendicular to a top surface of silicon layer 26. Application of the magnetic field is depicted by broken arrow M in FIG. 1(B) (arrow M being broken to reflect the fact that the magnetic field is not applied in all modes served for illustration purposes by FIG. 1(B)). The magnetic field is applied at approximately 300 kA/m.

The energy of the irradiating beam 32 of the laser 38C transforms to heat energy and causes a first melting in a region of the amorphous silicon layer 26 which was in the field of the beam 32. The melting occurs essentially through the entire thickness of the layer 26 in the irradiated region. The silicon layer 26 has low electric conductivity at room temperature, but high electric conductivity when it melts. As the melted silicon cools, the silicon crystallizes. In particular, a polycrystalline microstructure is formed in the irradiated region of the silicon layer 26 by lateral solidification from a boundary. In the process of silicon crystallization, sequential lateral growth crystals occur from the interface of the non-melting area and the melting area, meaning, e.g., that the silicon material moves in the melted area. Due to interaction between the magnetic field (generated by magnet 70C) and this silicon material movement, a small electromotive force occurs. Then the interaction of the magnetic field and the electromotive force causes the length and width of the lateral growth crystals to become large and the orientation of the lateral growth crystals to become uniform. Moreover, in the process of silicon crystallization of the eleventh mode, the aluminum nitride high thermal conductivity layer 24 widely spreads the heat received from the irradiation and makes the cooling velocity of the silicon uniform. The fact that the cooling occurs uniformly (rather than having rapid cooling in a specific sub-region as compared to other parts of the irradiated region) reduces occurrence of microcrystals in the center of the melted region.

FIG. 4(A) is a diagrammatic representation of crystallized microstructure CM(A) which exists in a region R(A) after a first time laser irradiation (e.g., before any overlapping regions are sequentially exposed) in accordance with the eleventh mode. By contrast, FIG. 4(B) depicts crystallized microstructure CM(B) which results from other processes after one time laser irradiation. In particular, in the process which resulted in the crystallized microstructure CM(B) of FIG. 4(B), a short pulse duration laser was utilized but no magnetic field was applied.

The lengths of the crystals which result from the eleventh mode are illustrated as arrow L(A) in FIG. 4(A) and are on the order of 4.0 μm. The widths of the crystals which result from the eleventh mode (measured in the direction illustrated as arrow W(A) in FIG. 4(A)) reach 1.5 μm. The effectiveness of the eleventh mode is apparent from the fact that, e.g., the lengths of the crystals of FIG. 4(B) are shorter, i.e., about 2.5 μm, and the widths of the crystals of FIG. 4(B) are narrower, i.e., on the order of about 0.8 μm.

### Twelfth Mode

In accordance with a twelfth mode, layer 24 of the semiconductor device 20 of FIG. 1(A) is a silicon dioxide layer which is formed on transparent substrate 22. The silicon dioxide layer 24 is deposited on transparent substrate 22 using any suitable technique, such as evaporation, ion-plating, sputtering, etc. An example thickness of the silicon dioxide layer 24 is 150 nm. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

For the twelfth mode, steps performed after the depositions of the silicon dioxide layer 24 and silicon layer 26 on transparent substrate 22 as aforedescribed are performed in a system such as system 30D of FIG. 2(D). In system 30D, the semiconductor device 20 is placed on sample stage 32. At room temperature, a surface (e.g., top surface) of the silicon layer 26 is irradiated by a beam 36 emitted from pulsed laser 38 (a pulse duration extended laser) and a magnetic field is applied by magnet magnetic field generator 70 (see FIG. 2(D)). The beam 36 of the laser 38 is directed parallel to axis F shown in FIG. 1(A), and the lines of force of the magnetic field are also parallel to the axis F. In other words, the magnetic field is perpendicular to a top surface of silicon layer 26. Application of the magnetic field is depicted by broken arrow M in FIG. 1(A). The magnetic field is applied at approximately 200 kA/m (e.g., 100 kA/m less than the magnetic field applied in the tenth mode).

The energy of the irradiating beam 32 of the laser 38 transforms to heat energy and causes a first melting in a region of the amorphous silicon layer 26 which was in the field of the beam 32. The melting occurs essentially through the entire thickness of the layer 26 in the irradiated region. The silicon layer 26 has low electric conductivity at room temperature, but high electric conductivity when it melts. As the melted silicon cools, the silicon crystallizes. In particular, a polycrystalline microstructure is formed in the irradiated region of the silicon layer 26 by lateral solidification from a boundary. In the process of silicon crystallization, sequential lateral growth crystals occur from the interface of the non-melting area and the melting area, meaning, e.g., that the silicon material moves in the melted area. Due to interaction between the magnetic field (generated by magnetic field generator 70) and this silicon material movement, a small electromotive force occurs. Then the interaction of the magnetic field and the electromotive force causes the length and width of the lateral growth crystals to become large and the orientation of the lateral growth crystals to become uniform. FIG. 4(A) is a diagrammatic representation of crystallized microstructure CM(A) which exists in a region R(A) after a first time laser irradiation (e.g., before any overlapping regions are sequentially exposed) in accordance with the twelfth mode. By contrast, FIG. 4(B) depicts crystallized microstructure CM(B) which results from other processes after one time laser irradiation. In particular, in the process which resulted in the crystallized microstructure CM(B) of FIG. 4(B), an extended pulse duration laser was utilized but no magnetic field was applied.

Whereas FIG. 4(A) shows crystallized microstructure after a first time or one-shot process in accordance with the twelfth mode, FIG. 5(A) is a diagrammatic representation of crystallized microstructure CM(A) after repeated stepped laser irradiation using a sequential lateral solidification (SLS) method in accordance with the twelfth mode. Whereas the one shot process which yields the structure of FIG. 4(A) a resultant device such as a TFT must be made in the crystal grain, in the SLS method of FIG. 5(A) the TFT device can be made anywhere along the SLS direction.

By contrast, FIG. 5(B) depicts crystallized microstructure CM(A) which exists after repeated stepped laser irradiation using a sequential lateral solidification (SLS) method in accordance with the process utilized to produce FIG. 4(B), i.e., using an extended pulse duration laser but no magnetic field.

The lengths of the crystals which result from the twelfth mode are illustrated as arrow L(A) in FIG. 4(A) and are on the order of 2.5 μm. The widths of the crystals which result from the twelfth mode (measured in the direction illustrated as arrow W(A) in FIG. 4(A)) reach 0.8 μm. The effectiveness of the twelfth mode is apparent from the fact that, e.g., the length of the crystals of FIG. 4(B) are shorter, i.e., about 1.0 μm and the widths of the crystals of FIG. 4(B) are narrower, i.e., on the order of about 0.5 μm. In FIG. 5(A) and FIG. 5(B), the white area is (111) orientation, the light gray area is (101) orientation, and the deep gray area is (100) orientation along the G-H axis. The contrast of FIG. 5(A) and FIG. 5(B) indicate that the twelfth mode has more uniformity in crystal orientation than the prior art.

### Thirteenth Mode

In accordance with a thirteenth mode, layer 24B of the semiconductor device 20B of FIG. 1(B) is a high thermal conductivity layer which is formed on transparent substrate 22. Layer 28 of semiconductor device 20B is a low thermal conductivity layer. Both the thermal conductivity layer 24B and the low thermal conductivity layer 28 can be deposited (separately) using any suitable technique, such as evaporation, ion-plating, sputtering, etc. Layer 26 of the semiconductor device 20 of FIG. 1(A) is silicon layer 26 which can be deposited on layer 24 by a technique such as (for example) plasma enhanced chemical vapor deposition (PECVD), evaporation, sputtering, etc. As initially deposited, the silicon layer 26 has an amorphous silicon microstructure. An example thickness of the silicon layer 26 is 50 nm.

In the representative example implementation of the thirteenth mode now discussed, an example material for the low thermal conductivity layer 28 is silicon oxide formed in a layer having a thickness of about 10 nm. Also in the particular example implementation now discussed, a representative example for the high thermal conductivity layer 24 is a layer made of aluminum nitride. An example thickness of the aluminum nitride high thermal conductivity layer 24 is 25 nm. It should be understood that the composition of the high thermal conductivity layer 24 is not limited to aluminum nitride. Rather, any high thermal conductivity material such as those discussed with reference to the preceding second through seventh modes can instead be utilized for high thermal conductivity layer 24.

For the thirteenth mode, steps performed after the depositions of the aluminum nitride high thermal conductivity layer 24, the low thermal conductivity layer 28, and the silicon layer 26 on transparent substrate 22 as aforedescribed are performed at room temperature in a system such as system 30(D) of FIG. 2(D). At room temperature, a surface (e.g., top surface) of the silicon layer 26 is irradiated by a beam 36 emitted from pulsed laser 38C (an extended pulse duration laser) and a magnetic field is applied by magnetic field generator 70D (see FIG. 2(D)). The beam 36 of the laser 38 is directed parallel to axis F shown in FIG. 1(A), and the lines of force of the magnetic field are also parallel to the axis F. In other words, the magnetic field is perpendicular to a top surface of silicon layer 26. Application of the magnetic field is depicted by broken arrow M in FIG. 1(B). The magnetic field is applied at approximately 200 kA/m (e.g., 100 kA/m less than the magnetic field applied in the eleventh mode)

The energy of the irradiating beam 32 of the laser 38 transforms to heat energy and causes a first melting in a region of the amorphous silicon layer 26 which was in the field of the beam 32. The melting occurs essentially through the entire thickness of the layer 26 in the irradiated region. The silicon layer 26 has low electric conductivity at room temperature, but high electric conductivity when it melts. As the melted silicon cools, the silicon crystallizes. In particular, a polycrystalline microstructure is formed in the irradiated region of the silicon layer 26 by lateral solidification from a boundary. In the process of silicon crystallization, sequential lateral growth crystals occur from the interface of the non-melting area and the melting area, meaning, e.g., that the silicon material moves in the melted area. Due to interaction between the magnetic field (generated by magnetic field generator 70) and this silicon material movement, a small electromotive force occurs. Then the interaction of the magnetic field and the electromotive force causes the length and width of the lateral growth crystals to become large and the orientation of the lateral growth crystals to become uniform. Moreover, in the process of silicon crystallization of the eleventh mode, the aluminum nitride high thermal conductivity layer 24 widely spreads the heat received from the irradiation and makes the cooling velocity of the silicon uniform. The fact that the cooling occurs uniformly (rather than having rapid cooling in a specific sub-region as compared to other parts of the irradiated region) reduces occurrence of microcrystals in the center of the melted region.

FIG. 4(A) is a diagrammatic representation of crystallized microstructure CM(A) which exists in a region R(A) after a first time laser irradiation (e.g., before any overlapping regions are sequentially exposed) in accordance with the thirteenth mode. By contrast, FIG. 4(B) depicts crystallized microstructure CM(B) which results from other processes after one time laser irradiation. In particular, in the process which resulted in the crystallized microstructure CM(B) of FIG. 4(B), a short pulse duration laser was utilized but no magnetic field was applied.

The lengths of the crystals which result from the thirteenth mode are illustrated as arrow L(A) in FIG. 4(A) and are on the order of 4.0 μm. The widths of the crystals which result from the thirteenth mode (measured in the direction illustrated as arrow W(A) in FIG. 4(A)) reach 1.5 μm. The effectiveness of the first mode is apparent from the fact that, e.g., the length of the crystals of FIG. 4(B) are shorter, i.e., about 2.5 μm, and the the widths of the crystals of FIG. 4(B) are narrower, i.e., on the order of about 0.8 μm.

### Laser Irradiating Manufacturing Systems

The various modes described herein can be implemented by suitable laser irradiating manufacturing systems, example systems being illustrated in non-limiting fashion by FIG. 2(A), FIG. 2(B), FIG. 2(C), and FIG. 2(D). The irradiation system 30(B) of FIG. 2(B) can be utilized for the second through eighth modes discussed above; the irradiation system 30 of FIG. 2(A) can be utilized for the first and ninth modes discussed above; the irradiation system 30(C) of FIG. 2(C) can be utilized for the tenth and eleventh modes discussed above; the irradiation system 30(D) of FIG. 2(D) can be utilized for the twelfth and thirteenth modes discussed above

The irradiation systems 30A-30D all include various common elements. For example, these irradiation systems include a sample stage 32 upon which the semiconductor device is positioned. A beam 36 from a pulsed laser 38 is focused on the semiconductor device.

For irradiation systems 30A, 30B, and 30D, the beam initially generated by the pulsed laser 38 is directed by mirror 39 to pulse duration extender 40. The pulse extended beam exiting pulse duration extender 40 is directed by mirror 42 to attenuator 44.

The irradiation system 30C of FIG. 2(C) does not use the pulse duration extender 40, but instead operates its laser as a short pulse duration laser (distinguished herein as pulsed laser 38C). The beam from pulsed laser 38C impinges directly on attenuator 44.

For all irradiation systems 30A-30D, other optics (e.g., mirrors 46, 48) direct the attenuated beam to field lens 50. Upon exiting field lens 50 the beam is incident upon mask 52 having slit(s) to define one or more beam slits. The beam slits are incident upon objective lens 54 and are directed by mirror 56 as the beam(s) 36 which focus on the semiconductor device situated on sample stage 32. For an optical system which has a demagnification of 5:1 and wherein it is desired to have a 5 μm region on the sample, a mask having a slit(s) of 25 μm can be used.

As mentioned above, the pulsed laser 38 can be an excimer laser, for example an excimer laser characterized by a wavelength of 308 nm and using XeCl gas. An example model is the COMPex® 301 series of excimer lasers marketed by Lambda Physik Corporation. It will be appreciated that other types of lasers, such as a continuous wave solid laser, for example, could instead be used.

A pulse duration extender such as pulse duration extender 40 typically has pairs of mirrors for lengthening the light path of the laser beam. In the illustrated systems, the pulse duration extender 40 extends the pulse duration by a factor of seven times longer than the original pulse duration of 30 ns (e.g., 7×30 ns=210 ns). The pulse duration extender 40 comprises several sets of half mirrors and mirrors.

As alluded to earlier, the irradiation system 30 of FIG. 2(A) includes heating device 34. Heating device 34 generically represents any form of heating apparatus suitable for heating the semiconductor device on or proximate the sample stage 32. For example, the heating device 34 can be an integral or auxiliary part of sample stage 32. Alternatively, the heating device 34 can be a light source or electromagnetic wave source positioned proximate the sample stage 32 (for, e.g., directing heat or heating beams from above). The light source can be a lamp, infra-red heater, or laser (e.g., even an auxiliary beam divided by a mirror from the main beam from laser 38, for example).

The irradiation system 30C of FIG. 2(C) and the irradiation system 30D of FIG. 2(D) includes apparatus for generating the magnetic field. The apparatus for generating the magnetic field may be a magnet (e.g., permanent magnet 70C) located in the sample stage 32 as shown in FIG. 2(C), or an electromagnet 70D situated above sample stage 32 as shown in FIG. 2(D). In the latter case of the magnet being situated above sample stage 32, the magnet core may take the form of a ring through which the laser beam 36 is directed. Other means for generating the magnetic field are also encompassed, such as an electromagnet on the sample stage 32, for example.

The irradiation system 30 of FIG. 2(A), the irradiation system 30(B) of FIG. 2(B), and the irradiation system 30(C) of FIG. 2(C) can each further include a controller 60. The controller 60 controls or supervises, e.g., the pulsed laser 38 and the sample stage 32. The controller 60 can also adjust the timing of the laser irradiation and the position of sample stage 32. For example, the controller 60 can supervise movement of sample stage 32 in the direction depicted by arrows 62 in FIG. 2(A), FIG. 2(B), and FIG. 2(C). Movement of the sample stage 32 under supervision of controller 60 can be used to position sequential regions of the semiconductor device in view of the pulsed laser 38, and preferably to position sequential adjacent or partially overlapping regions of the semiconductor device in view of the pulsed laser 38 in accordance with the sequential lateral solidification (SLS) method. Moreover, the controller 60 can also optionally control or supervise operation of the magnetic field generator 70 in appropriate embodiments, at least for applying the magnetic field while the laser irradiates the sample.

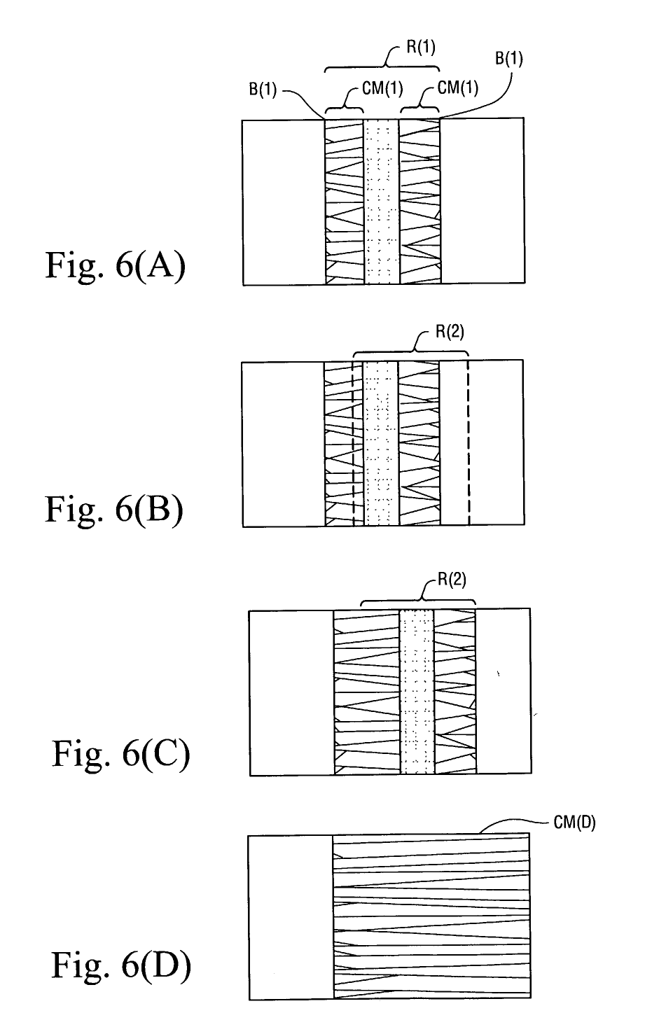

As mentioned above, in the sequential lateral solidification (SLS) method crystals grow in the horizontal direction after irradiation. FIG. 6(A) through FIG. 6(D), somewhat like FIG. 3(A), FIG. 3(B), and FIG. 3(C), depict by way of example the appearance of the silicon layer including the crystallized microstructures during a process of sequential laser irradiation of adjacent or at least partially overlapping regions in accordance with the sequential lateral solidification (SLS) method.

FIG. 6(A) shows crystallized microstructure CM(1) which exists in an irradiated region R(1) after a first irradition. Heating of the silicon layer 26 occurs, e.g., by heat from the pulsed laser 38, with the mask slit 52 being employed to cover all areas except the region R(1). The energy of pulsed laser 38 transfers to heat energy and melts the silicon in the region R(1) through the thickness of silicon layer 26 completely. Then, as the silicon layer 26 cools, the region R(1) solidifies with crystals growing toward the center of region R(1) from boundaries of the region (the boundaries being represented by lines B(1) in FIG. 6(A)). The boundaries of the region are essentially interfaces between the melted silicon of the irradiated region and non-melted silicon outside the irradiated region.

Translation or movement of the sample stage 32 in the direction of arrow 62 (or alternatively an equivalent movement or displacement of the laser) results in the slitted beam of pulsed laser 38 having a field of view as shown in FIG. 6(B) on another region R(2) of the semiconductor device. The region R(2) of FIG. 6(2) is adjacent to or partially overlaps region R(1) of FIG. 6(A), and preferably includes portions of region R(1) which were not crystallized in the first irradiation of FIG. 6(A). FIG. 6(C) depicts the region R(2) after a laser irradiation of region R(2), i.e., the second laser irradiation of the semiconductor device. FIG. 6(C) shows the horizontal growth of large grain sized polycrystals in region R(2). It will be appreciated that sequential laser irradiations for adjacent or at least overlapping further regions will ultimately result in a crystalline microstructure CM(D) comparable to that shown in FIG. 6(D).

The larger and wider crystals formed in accordance with the modes hereof result, e.g., in higher mobility semiconductor devices. The higher mobility provides improved behavior of devices, e.g., improved switching for pixels in a semiconductor display, for example.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims. For example, while the semiconductor devices described and specifically illustrated herein have primarily involved uniform cooling of devices formed from an amorphous silicon film on a substrate, it will be understood that the same principles are applicable for achieving uniform cooling of devices formed from a microcrystallized silicon film formed on a substrate.

What is claimed is:

1. A method for manufacturing a semiconductor device comprising:
(1) forming a semiconductor material on a substrate;
(2) irradiating at least a region of the semiconductor material with a laser for heating and melting the semiconductor material in the region;
(3) promoting uniform cooling of the silicon film after irradiation;
so that a polycrystalline microstructure is formed in the semiconductor material by lateral solidification from a boundary of the region.

2. A method for manufacturing a semiconductor device comprising:
(1) forming a semiconductor material on a substrate;
(2) irradiating at least a region of the semiconductor material with a laser for heating and melting the semiconductor material in the region;
(3) heating the semiconductor material to a temperature in a range from 300 degrees Centigrade to a crystallization temperature of the semiconductor material;
whereby after irradiation a polycrystalline microstructure is formed in the semiconductor material by lateral solidification from a boundary of the region.

3. A method for manufacturing a semiconductor device comprising:
(1) forming a semiconductor material on a substrate;
(2) irradiating at least a region of the semiconductor material with a laser for heating and melting the semiconductor material in the region;
(3) providing a high thermal conductivity material in proximity to the semiconductor material, the high thermal conductivity material spreading heat in the region and promoting uniform cooling in the region;
whereby after irradiation a polycrystalline microstructure is formed in the semiconductor material by lateral solidification from a boundary of the region.

4. The method of claims 1, 2, or 3, wherein the semiconductor material is a silicon film.

5. The method of claims 1, 2, or 3, further comprising directing a beam from the laser through a mask slit and onto the semiconductor material.

6. The method of claims 1, 2, or 3, wherein the laser is an extended laser or a continuous wave laser.

7. The method of claims 1 or 3, further comprising heating the semiconductor material to a temperature in a range from 300 degrees Centigrade to a crystallization temperature of the semiconductor material.

8. The method of claim 3, further comprising forming the high thermal conductivity material between the semiconductor material and the substrate.

9. The method of claim 8, further comprising forming a low thermal conductivity material between the high thermal conductivity material and the semiconductor material.

10. The method of claim 8, wherein the high thermal conductivity material is one of aluminum nitride; silicon nitride; a mixture of aluminum nitride and silicon nitride; magnesium oxide; cerium oxide; titanium nitride.

11. The method of claim 8, wherein the high thermal conductivity material has a thermal conductivity of 10 W/mK or higher.

12. The method of claims 1, 2, or 3, further comprising applying a magnetic field perpendicular to a surface of the semiconductor material

13. The method of claim 12, further comprising creating an electromotive force by application of the magnetic field and movement of melted silicon, the electromotive force serving to lengthen and widen lateral growth crystals in the polycrystalline microstructure.

14. The method of claim 12, further comprising directing a beam from the laser through a mask slit and through the magnetic field onto the semiconductor material.

15. The method of claim 12, further comprising using a magnet in a sample stage to apply the magnetic field.

16. The method of claims 1, 2, or 3, further comprising performing step (2) for adjacent or at least partially overlapping regions of the semiconductor device.

17. The method of claims 1, 2, or 3, whereby a grain size of the polycrystalline microstructure is uniformly increased in length and width.

18. A semiconductor device comprising:
a semiconductor material formed on a substrate, the semiconductor material having a polycrystalline microstructure formed by lateral solidification after melting using laser irradiation;
a high thermal conductivity material in proximity to the semiconductor material which served for spreading heat in and promoting uniform cooling in the region after the irradiation.

19. The device of claim 18, wherein the high thermal conductivity material is between the semiconductor material and the substrate.

20. The device of claim 19, further comprising a low thermal conductivity material between the high thermal conductivity material and the semiconductor material.

21. The device of claim 18, wherein the high thermal conductivity material has a thermal conductivity of 10 W/mK or higher.

22. The device of claim 18, wherein the high thermal conductivity material is one of aluminum nitride; silicon nitride; a mixture of aluminum nitride and silicon nitride; magnesium oxide; cerium oxide; titanium nitride.

23. A semiconductor device produced by the process of claim 1.

24. A semiconductor device produced by the process of claim 2.

25. A semiconductor device produced by the process of claim 3.

26. A semiconductor device produced by the process of claim 4.

27. A semiconductor device produced by the process of claim 5.

28. A semiconductor device produced by the process of claim 6.

29. A semiconductor device produced by the process of claim 7.

30. A semiconductor device produced by the process of claim 8.

31. A semiconductor device produced by the process of claim 9.

32. A semiconductor device produced by the process of claim 10.

33. A semiconductor device produced by the process of claim 11.

34. A semiconductor device produced by the process of claim 12.

35. A semiconductor device produced by the process of claim 13.

36. A semiconductor device produced by the process of claim 14.

37. A semiconductor device produced by the process of claim 15.

38. A semiconductor device produced by the process of claim 16.

39. A semiconductor device produced by the process of claim 17.

40. A semiconductor device produced by the process of claim 18.

41. A semiconductor device produced by the process of claim 19.

42. A semiconductor device produced by the process of claim 20.

43. A semiconductor device produced by the process of claim 21.

44. A semiconductor device produced by the process of claim 22.
